(19) United States
(12) Patent Application Publication
(10) Pub. No.: US 2005/0208746 A1
(43) Pub. Date: Sep. 22, 2005

(54) Low cost electrically conductive flooring tile manufactured from conductive loaded resin-based materials

(75) Inventor: Thomas Aisenbrey, Littleton, CO (US)

Correspondence Address: STEPHEN B. ACKERMAN, 28 DAVIS AVENUE, POUGHKEEPSIE, NY, 12603, US

(73) Assignee: Integral Technologies, Inc.

(21) Appl. No.: 11/127,571

(22) Filed: May 12, 2005

Related U.S. Application Data
(63) Continuation-in-part of application No. 10/877,092, filed on Jun. 25, 2004.
Application No. 10/877,092 is a continuation of application No. 10/309,429, filed on Dec. 4, 2002, now Pat. No. 6,870,516.
Application No. 10/309,429 is a continuation-in-part of application No. 10/075,778, filed on Feb. 14, 2002, now Pat. No. 6,741,221.
(60) Provisional application No. 60/570,633, filed on May 13, 2004.
(60) Provisional application No. 60/317,808, filed on Sep. 7, 2001.
(60) Provisional application No. 60/269,414, filed on Feb. 16, 2001.
(60) Provisional application No. 60/268,822, filed on Feb. 15, 2001.

(51) Int. Cl. B32B 5/02; B32B 27/04; B32B 27/12; B32B 3/26; H01L 21/44

(52) U.S. Cl. 438/610; 428/304.4; 428/318.4

(57) ABSTRACT

Electrically conductive flooring is formed of a conductive loaded resin-based material. The conductive loaded resin-based material comprises micron conductive powder(s), conductive fiber(s), or a combination of conductive powder and conductive fibers in a base resin host. The percentage by weight of the conductive powder(s), conductive fiber(s), or a combination thereof is between about 20% and 50% of the weight of the conductive loaded resin-based material. The micron conductive powders are metals or conductive non-metals or metal plated non-metals. The micron conductive fibers may be metal fiber or metal plated fiber. Further, the metal plated fiber may be formed by plating metal onto a metal fiber or by plating metal onto a non-metal fiber. Any platable fiber may be used as the core for a non-metal fiber. Superconductor metals may also be used as micron conductive fibers and/or as metal plating onto fibers in the present invention.

### RELATED PATENT APPLICATIONS

This Patent Application is related to U.S. patent application INT04-014B, Ser. No. ______, and filed on ______, which is herein incorporated by reference in its entirety.

This Patent Application claims priority to the U.S. Provisional Patent Application 60/570,633, filed on May 13, 2004, which is herein incorporated by reference in its entirety.

This Patent Application is a Continuation-in-Part of INT01-002CIPC, filed as U.S. patent application Ser. No. 10/877,092, filed on Jun. 25, 2004, which is a Continuation of INT01-002CIP, filed as U.S. patent application Ser. No. 10/309,429, filed on Dec. 4, 2002, now issued as U.S. Pat. No. 6,870,516, also incorporated by reference in its entirety, which is a Continuation-in-Part application of docket number INT01-002, filed as U.S. patent application Ser. No. 10/075,778, filed on Feb. 14, 2002, now issued as U.S. Pat. No. 6,741,221, which claimed priority to U.S. Provisional Patent Applications Ser. No. 60/317,808, filed on Sep. 7, 2001, Ser. No. 60/269,414, filed on Feb. 16, 2001, and Ser. No. 60/268,822, filed on Feb. 15, 2001, all of which are incorporated by reference in their entirety.

### BACKGROUND OF THE INVENTION

(1) Field of the Invention

This invention relates to flooring tile and, more particularly, to electrically conductive flooring tile molded of conductive loaded resin-based materials comprising micron conductive powders, micron conductive fibers, or a combination thereof, substantially homogenized within a base resin when molded. This manufacturing process yields a conductive part or material usable within the EMF or electronic spectrum(s).

(2) Description of the Prior Art

Electrostatic discharge (ESD) is a significant issue in any environment containing electronic devices. ESD events can generate greater than 10,000 volts. This voltage is sufficient to permanently damage electronic circuits, particularly those that rely on very thin silicon dioxide control gates. Electrostatic charging is typically generated by movement and, most typically, by the movement of people in tasks such as walking across a floor, rising from a chair, or sliding objects on a table. To prevent damage from ESD, techniques are employed to reduce the build-up of charge and/or to dissipate the energy of a discharge into a safe object. Reduction of charge build-up is accomplished by providing a conductive path to ground to keep the person, or other potential charging objects, from becoming charged. Dissipation of an ESD event is accomplished by providing a conductive, though somewhat resistive, path to ground to convert the discharge energy into heat while shunting this energy away from electronic devices that could be damaged during by the event.

To achieve an Electrostatic Discharge (ESD) controlled environment, the static generated by walking on the floor must typically be kept below 0.2 kV (200 volts). Conductive flooring tile is frequently used in ESD controlled areas, such as those involved in electronic-component assembly or where electronic components and/or circuit boards are routinely handled, to dissipate the static electricity induced by movement of people and equipment within the area. One prior art approach to ESD dissipating flooring is to form the flooring from pure vinyl or from vinyl with a small amount of carbon filler. Companies such as UltraStat 2000 Inc., Colorado City, Colo. 81019; Julie Industries, Wilmington, Mass. 01887; Shakespeare Monofilaments and Specialty Polymers, Columbia, S.C. 29223; and Tarkett SAS, Nanterre Cedex, France manufacture conductive flooring tile and material for the dissipation of the electrostatic discharges.

Several prior art inventions relate to conductive flooring materials. U.S. Pat. No. 5,307,233 to Forry teaches electrically conductive material comprising polyvinyl chloride pellets coated with carbon black or zinc oxide. U.S. Pat. No. 4,521,553 to Fitton et al teaches anti-static, highly plasticized polyvinylchloride incorporating carbon fibers. U.S. Pat. No. 4,944,998 to Ko et al teaches charge dissipating floor tiles with carbon or metal fillers in polyvinyl chloride. U.S. Pat. No. 4,084,031 to Barsy teaches a static discharge floor covering with incorporated gaps or discontinuities to improve performance. U.S. Pat. No. 5,443,897 to Kawaguchi et al teaches an electrically conductive decorative material comprising a thermoplastic resin and conductive fiber including carbon fiber, metal fiber, fiber of vacuum deposited metal, and the like.

### SUMMARY OF THE INVENTION

A principal object of the present invention is to provide effective conductive flooring.

A further object of the present invention is to provide conductive floor tile.

A further object of the present invention is to provide conductive floor sheeting.

A further object of the present invention is to provide a method to form conductive flooring.

A further object of the present invention is to provide conductive flooring molded of conductive loaded resin-based materials.

A yet further object of the present invention is to provide a conductive flooring molded of conductive loaded resin-based material where the electrical, thermal, or ESD characteristics can be altered or the visual characteristics can be altered by forming a metal layer over the conductive loaded resin-based material.

A yet further object of the present invention is to provide methods to fabricate a conductive flooring from a conductive loaded resin-based material incorporating various forms of the material.

In accordance with the objects of this invention, a conductive flooring device is achieved. The device comprises a conductive loaded, resin-based material comprising conductive materials in a base resin host. The weight of the conductive materials is between 20% and 50% of the total weight of the conductive loaded resin-based material.

Also in accordance with the objects of this invention, a conductive flooring device is achieved. The device comprises a conductive loaded, resin-based material comprising micron conductive fiber in a base resin host. The weight of the micron conductive fiber is between 20% and 50% of the total weight of the conductive loaded resin-based material.

Also in accordance with the objects of this invention, a conductive flooring device is achieved. The device comprises a first layer comprising a first conductive loaded, resin-based material comprising conductive materials in a base resin host. The weight of the conductive materials is between 20% and 50% of the total weight of the first conductive loaded resin-based material. The conductive loaded resin-based material is a solid. A second layer comprises a second conductive loaded resin-based material comprising conductive materials in a base resin host. The second conductive loaded resin-based material is a foamed material.

Also in accordance with the objects of this invention, a method to form a conductor roofing device is achieved. The method comprises providing a conductive loaded, resin-based material comprising conductive materials in a resin-based host. The weight of the conductive materials is between 20% and 50% of the total weight of the conductive loaded resin-based material. The conductive loaded, resin-based material is molded into a conductive flooring device.

Also in accordance with the objects of this invention, a method to form a conductive roofing-device is achieved. The method comprises providing a conductive loaded, resin-based material comprising conductive materials in a resin-based host. The percent by weight of the conductive materials is between 20% and 40% of the total weight of the conductive loaded resin-based material. The conductive loaded, resin-based-material is molded into a conductive flooring device.

Also in accordance with the objects of this invention, a method to form a conductive roofing device is achieved. The method comprises providing a conductive loaded, resin-based material comprising micron conductive fiber in a resin-based host. The percent by weight of the micron conductive fiber is between 25% and 35% of the total weight of the conductive loaded resin-based material. The conductive loaded, resin-based material is molded into a conductive flooring device.

### BRIEF DESCRIPTION OF THE DRAWINGS

In the accompanying drawings forming a material part of this description, there is shown:

FIG. 1 illustrates a first preferred embodiment of the present invention showing an electrically conductive flooring tile comprising a conductive loaded resin-based material.

FIG. 2 illustrates a first preferred embodiment of a conductive loaded resin-based material wherein the conductive materials comprise a powder.

FIG. 3 illustrates a second preferred embodiment of a conductive loaded resin-based material wherein the conductive materials comprise micron conductive fibers.

FIG. 4 illustrates a third preferred embodiment of a conductive loaded resin-based material wherein the conductive materials comprise both conductive powder and micron conductive fibers.

FIGS. 5a and 5b illustrate a fourth preferred embodiment wherein conductive fabric-like materials are formed from the conductive loaded resin-based material.

FIGS. 6a and 6b illustrate, in simplified schematic form, an injection molding apparatus and an extrusion molding apparatus that may be used to mold electrically conductive flooring tile of a conductive loaded resin-based material.

FIG. 7 illustrates a second embodiment of electrically conductive flooring tile formed of conductive loaded resin-based material according to the present invention.

### DESCRIPTION OF THE PREFERRED EMBODIMENTS

This invention relates to electrically conductive flooring tile molded of conductive loaded resin-based materials comprising micron conductive powders, micron conductive fibers, or a combination thereof, substantially homogenized within a base resin when molded.

The conductive loaded resin-based materials of the invention are base resins loaded with conductive materials, which then makes any base resin a conductor rather than an insulator. The resins provide the structural integrity to the molded part. The micron conductive fibers, micron conductive powders, or a combination thereof, are substantially homogenized within the resin during the molding process, providing the electrical continuity.

The conductive loaded resin-based materials can be molded, extruded or the like to provide almost any desired shape or size. The molded conductive loaded resin-based materials can also be cut, stamped, or vacuumed formed from an injection molded or extruded sheet or bar stock, calendaring, over-molded, laminated, milled or the like to provide the desired shape and size. The thermal or electrical conductivity characteristics of electrically conductive flooring tile fabricated using conductive loaded resin-based materials depend on the composition of the conductive loaded resin-based materials, of which the loading or doping parameters can be adjusted, to aid in achieving the desired structural, electrical or other physical characteristics of the material. The selected materials used to fabricate the electrically conductive flooring tile devices are substantially homogenized together using molding techniques and or methods such as injection molding, over-molding, insert molding, thermo-set, protrusion, extrusion or the like. Characteristics related to 2D, 3D, 4D, and 5D designs, molding and electrical characteristics, include the physical and electrical advantages that can be achieved during the molding process of the actual parts and the polymer physics associated within the conductive networks within the molded part(s) or formed material(s).

In the conductive loaded resin-based material, electrons travel from point to point when under stress, following the path of least resistance. Most resin-based materials are insulators and represent a high resistance to electron passage. The doping of the conductive loading into the resin-based material alters the inherent resistance of the polymers. At a threshold concentration of conductive loading, the resistance through the combined mass is lowered enough to allow electron movement. Speed of electron movement depends on conductive loading concentration, that is, the separation between the conductive loading particles. Increasing conductive loading content reduces interparticle separation distance, and, at a critical distance known as the percolation point, resistance decreases dramatically and electrons move rapidly.

Resistivity is a material property that depends on the atomic bonding and on the microstructure of the material. The atomic microstructure material properties within the conductive loaded resin-based material are altered when molded into a structure. A substantially homogenized conductive microstructure of delocalized valance electrons is created. This microstructure provides sufficient charge carriers within the molded matrix structure. As a result, a low density, low resistivity, lightweight, durable, resin based polymer microstructure material is achieved. This material exhibits conductivity comparable to that of highly conductive metals such as silver, copper or aluminum, while maintaining the superior structural characteristics found in many plastics and rubbers or other structural resin based materials.

The use of conductive loaded resin-based materials in the fabrication of electrically conductive flooring tile significantly lowers the cost of materials and the design and manufacturing processes used to hold ease of close tolerances, by forming these materials into desired shapes and sizes. The electrically conductive flooring tile can be manufactured into infinite shapes and sizes using conventional forming methods such as injection molding, over-molding, calendaring, or extrusion or the like. The conductive loaded resin-based materials, when molded, typically but not exclusively produce a desirable usable range of resistivity from between about 5 and 25 ohms per square, but other resistivities can be achieved by varying the doping parameters and/or resin selection(s).

The conductive loaded resin-based materials comprise micron conductive powders, micron conductive fibers, or any combination thereof, which are substantially homogenized together within the base resin, during the molding process, yielding an easy to produce low cost, electrically conductive, close tolerance manufactured part or circuit. The resulting molded article comprises a three dimensional, continuous network of conductive loading and polymer matrix. Exemplary micron conductive powders include carbons, graphites, amines or the like, and/or of metal powders such as nickel, copper, silver, aluminum, or plated or the like. The use of carbons or other forms of powders such as graphite(s) etc. can create additional low level electron exchange and, when used in combination with micron conductive fibers, creates a micron filler element within the micron conductive network of fiber(s) producing further electrical conductivity as well as acting as a lubricant for the molding equipment. The addition of conductive powder to a micron conductive fiber loading may increase the surface conductivity of the molded part, particularly in areas where a skinning effect occurs during molding.

The micron conductive fibers may be metal fiber or metal plated fiber. Further, the metal plated fiber may be formed by plating metal onto a metal fiber or by plating metal onto a non-metal fiber. Exemplary metal fibers include, but are not limited to, stainless steel fiber, copper fiber, nickel fiber, silver fiber, aluminum fiber, or the like, or combinations thereof. Exemplary metal plating materials include, but are not limited to, copper, nickel, cobalt, silver, gold, palladium, platinum, ruthenium, and rhodium, and alloys of thereof. Any platable fiber may be used as the core for a non-metal fiber. Exemplary non-metal fibers include, but are not limited to, carbon, graphite, polyester, basalt, man-made and naturally-occurring materials, and the like. In addition, superconductor metals, such as titanium, nickel, niobium, and zirconium, and alloys of titanium, nickel, niobium, and zirconium may also be used as micron conductive fibers and/or as metal plating onto fibers in the present invention.

The structural material is a material such as any polymer resin. Structural material can be, here given as examples and not as an exhaustive list, polymer resins produced by GE PLASTICS, Pittsfield, Mass., a range of other plastics produced by GE PLASTICS, Pittsfield, Mass., a range of other plastics produced by other manufacturers, silicones produced by GE SILICONES, Waterford, N.Y., or other flexible resin-based rubber compounds produced by other manufacturers.

The resin-based structural material loaded with micron conductive powders, micron conductive fibers, or in combination thereof can be molded, using conventional molding methods such as injection molding or over-molding, or extrusion to create desired shapes and sizes. The molded conductive loaded resin-based materials can also be stamped, cut or milled as desired to form create the desired shape form factor(s) of the electrically conductive flooring tile. The doping composition and directionality associated with the micron conductors within the loaded base resins can affect the electrical and structural characteristics of the tile and can be precisely controlled by mold designs, gating and or protrusion design(s) and or during the molding process itself. In addition, the resin base can be selected to obtain the desired thermal characteristics such as very high melting point or specific thermal conductivity.

A resin-based sandwich laminate could also be fabricated with random or continuous webbed micron stainless steel fibers or other conductive fibers, forming a cloth like material. The webbed conductive fiber can be laminated or the like to materials such as Teflon, Polyesters, or any resin-based flexible or solid material(s), which when discretely designed in fiber content(s), orientation(s) and shape(s), will produce a very highly conductive flexible cloth-like material. Such a cloth-like material could also be used in forming electrically conductive flooring tile that could be embedded in a person's clothing as well as other resin materials such as rubber(s) or plastic(s). When using conductive fibers as a webbed conductor as part of a laminate or cloth-like material, the fibers may have diameters of between about 3 and 12 microns, typically between about 8 and 12 microns or in the range of about 10 microns, with length(s) that can be seamless or overlapping.

The conductive loaded resin-based material of the present invention can be made resistant to corrosion and/or metal electrolysis by selecting micron conductive fiber and/or micron conductive powder and base resin that are resistant to corrosion and/or metal electrolysis. For example, if a corrosion/electrolysis resistant base resin is combined with stainless steel fiber and carbon fiber/powder, then a corrosion and/or metal electrolysis resistant conductive loaded resin-based material is achieved. Another additional and important feature of the present invention is that the conductive loaded resin-based material of the present invention may be made flame retardant. Selection of a flame-retardant (FR) base resin material allows the resulting product to exhibit flame retardant capability. This is especially important in electrically conductive flooring tile applications as described herein.

The substantially homogeneous mixing of micron conductive fiber and/or micron conductive powder and base resin described in the present invention may also be described as doping. That is, the substantially homogeneous mixing converts the typically non-conductive base resin material into a conductive material. This process is analogous to the doping process whereby a semiconductor material, such as silicon, can be converted into a conductive material through the introduction of donor/acceptor ions as is well known in the art of semiconductor devices. Therefore, the present invention uses the term doping to mean converting a typically non-conductive base resin material into a conductive material through the substantially homogeneous mixing of micron conductive fiber and/or micron conductive powder into a base resin.

As an additional and important feature of the present invention, the molded conductor loaded resin-based material exhibits excellent thermal dissipation characteristics. Therefore, electrically conductive flooring tile manufactured from the molded conductor loaded resin-based material can provide added thermal dissipation capabilities to the application. For example, heat can be dissipated from electrical devices physically and/or electrically connected to electrically conductive flooring tile of the present invention.

As a significant advantage of the present invention, electrically conductive flooring tile constructed of the conductive loaded resin-based material can be easily interfaced to an electrical circuit or grounded. In one embodiment, a wire can be attached to a conductive loaded resin-based electrically conductive flooring tile via a screw that is fastened to the tile. For example, a simple sheet-metal type, self tapping screw, when fastened to the material, can achieve excellent electrical connectivity via the conductive matrix of the conductive loaded resin-based material. To facilitate this approach a boss may be molded into the conductive loaded resin-based material to accommodate such a screw. Alternatively, if a solderable screw material, such as copper, is used, then a wire can be soldered to the screw that is embedded into the conductive loaded resin-based material. In another embodiment, the conductive loaded resin-based material is partly or completely plated with a metal layer. The metal layer forms excellent electrical conductivity with the conductive matrix. A connection of this metal layer to another circuit or to ground is then made. For example, if the metal layer is solderable, then a soldered connection may be made between the electrically conductive flooring tile and a grounding wire.

Where a metal layer is formed over the surface of the conductive loaded resin-based material, any of several techniques may be used to form this metal layer. This metal layer may be used for visual enhancement of the molded conductive loaded resin-based material article or to otherwise alter performance properties. Well-known techniques, such as electroless metal plating, electro metal plating, metal vapor deposition, metallic painting, or the like, may be applied to the formation of this metal layer. If metal plating is used, then the resin-based structural material of the conductive loaded, resin-based material is one that can be metal plated. There are many of the polymer resins that can be plated with metal layers. For example, GE Plastics, SUPEC, VALOX, ULTEM, CYCOLAC, UGIKRAL, STYRON, CYCOLOY are a few resin-based materials that can be metal plated. Electroless plating is typically a multiple-stage chemical process where, for example, a thin copper layer is first deposited to form a conductive layer. This conductive layer is then used as an electrode for the subsequent plating of a thicker metal layer.

A typical metal deposition process for forming a metal layer onto the conductive loaded resin-based material is vacuum metallization. Vacuum metallization is the process where a metal layer, such as aluminum, is deposited on the conductive loaded resin-based material inside a vacuum chamber. In a metallic painting process, metal particles, such as silver, copper, or nickel, or the like, are dispersed in an acrylic, vinyl, epoxy, or urethane binder. Most resin-based materials accept and hold paint well, and automatic spraying systems apply coating with consistency. In addition, the excellent conductivity of the conductive loaded resin-based material of the present invention facilitates the use of extremely efficient, electrostatic painting techniques.

The conductive loaded resin-based material can be contacted in any of several ways. In one embodiment, a pin is embedded into the conductive loaded resin-based material by insert molding, ultrasonic welding, pressing, or other means. A connection with a metal wire can easily be made to this pin and results in excellent contact to the conductive loaded resin-based material. In another embodiment, a hole is formed in to the conductive loaded resin-based material either during the molding process or by a subsequent process step such as drilling, punching, or the like. A pin is then placed into the hole and is then ultrasonically welded to form a permanent mechanical and electrical contact. In yet another embodiment, a pin or a wire is soldered to the conductive loaded resin-based material. In this case, a hole is formed in the conductive loaded resin-based material either during the molding operation or by drilling, stamping, punching, or the like. A solderable layer is then formed in the hole. The solderable layer is preferably formed by metal plating. A conductor is placed into the hole and then mechanically and electrically bonded by point, wave, or reflow soldering.

Another method to provide connectivity to the conductive loaded resin-based material is through the application of a solderable ink film to the surface. One exemplary solderable ink is a combination of copper and solder particles in an epoxy resin binder. The resulting mixture is an active, screen-printable and dispensable material. During curing, the solder reflows to coat and to connect the copper particles and to thereby form a cured surface that is directly solderable without the need for additional plating or other processing steps. Any solderable material may then be mechanically and/or electrically attached, via soldering, to the conductive loaded resin-based material at the location of the applied solderable ink. Many other types of solderable inks can be used to provide this solderable surface onto the conductive loaded resin-based material of the present invention. Another exemplary embodiment of a solderable ink is a mixture of one or more metal powder systems with a reactive organic medium. This type of ink material is converted to solderable pure metal during a low temperature cure without any organic binders or alloying elements.

A ferromagnetic conductive loaded resin-based material may be formed of the present invention to create a magnetic or magnetizable form of the material. Ferromagnetic micron conductive fibers and/or ferromagnetic conductive powders are mixed with the base resin. Ferrite materials and/or rare earth magnetic materials are added as a conductive loading to the base resin. With the substantially homogeneous mixing of the ferromagnetic micron conductive fibers and/or micron conductive powders, the ferromagnetic conductive loaded resin-based material is able to produce an excellent low cost, low weight magnetize-able item. The magnets and magnetic devices of the present invention can be magnetized during or after the molding process. The magnetic strength of the magnets and magnetic devices can be varied by adjusting the amount of ferromagnetic micron conductive fibers and/or ferromagnetic micron conductive powders that are incorporated with the base resin. By increasing the amount of the ferromagnetic doping, the strength of the magnet or magnetic devices is increased. The substantially homogenous mixing of the conductive fiber network allows for a substantial amount of fiber to be added to the base resin without causing the structural integrity of the item to decline. The ferromagnetic conductive loaded resin-based magnets display the excellent physical properties of the base resin, including flexibility, moldability, strength, and resistance to environmental corrosion, along with excellent magnetic ability. In addition, the unique ferromagnetic conductive loaded resin-based material facilitates formation of items that exhibit excellent thermal and electrical conductivity as well as magnetism.

A high aspect ratio magnet is easily achieved through the use of ferromagnetic conductive micron fiber or through the combination of ferromagnetic micron powder with conductive micron fiber. The use of micron conductive fiber allows for molding articles with a high aspect ratio of conductive fiber to cross sectional area. If a ferromagnetic micron fiber is used, then this high aspect ratio translates into a high quality magnetic article. Alternatively, if a ferromagnetic micron powder is combined with micron conductive fiber, then the magnetic effect of the powder is effectively spread throughout the molded article via the network of conductive fiber such that an effective high aspect ratio molded magnetic article is achieved. The ferromagnetic conductive loaded resin-based material may be magnetized, after molding, by exposing the molded article to a strong magnetic field. Alternatively, a strong magnetic field may be used to magnetize the ferromagnetic conductive loaded resin-based material during the molding process.

The ferromagnetic conductive loading is in the form of fiber, powder, or a combination of fiber and powder. The micron conductive powder may be metal fiber or metal plated fiber. If metal plated fiber is used, then the core fiber is a platable material and may be metal or non-metal. Exemplary ferromagnetic conductive fiber materials include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive fiber materials. Exemplary ferromagnetic micron powder leached onto the conductive fibers include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive powder materials. A ferromagnetic conductive loading may be combined with a non-ferromagnetic conductive loading to form a conductive loaded resin-based material that combines excellent conductive qualities with magnetic capabilities.

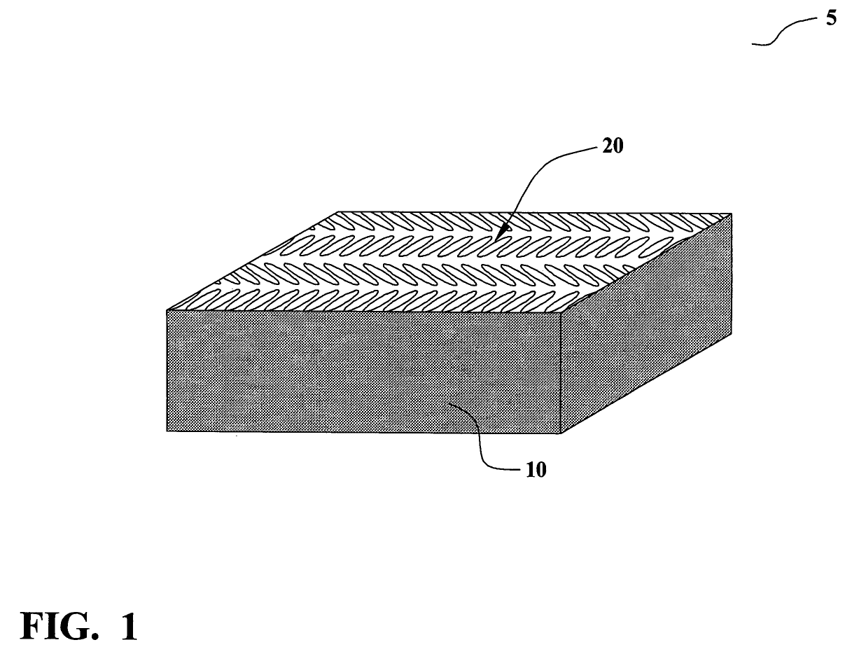

Referring now to FIG. 1, a first embodiment of the present invention is illustrated. A very low cost, flexible, electrically conductive flooring tile 5 comprising conductive loaded resin-based materials is shown. Several important features of the present invention are shown and discussed below. In one embodiment, the electrically conductive flooring tile 5 comprises a conductive substrate 10 of the conductive loaded resin-based material of the present invention. The level of conductive loading is selected to create a desired level of conductivity in the substrate 10. If it is desired to have a highly conductive flooring material to provide a consistent, low resistance path to ground throughout a room, then a relatively heavy loading is used. Conversely, if a more resistive flooring material is needed to provide an ESD dissipating flooring material, then a lower conductive loading is used.

The present invention provides an ESD material that is resistant to chemical reaction and corrosion based on the capabilities of the base resin. In addition, a base resin may be used with the desired properties for wear, clean-up, and strength. Additional coloring fillers may be added, as known in the art, to provide attract color varieties. In one embodiment, the present invention is formed into individual tiles 5 that can be applied for flooring, walls, ceilings, table or counter tops, and the like. In another embodiment, the present invention is formed into continuous sheets 5 for roll flooring, wall and ceiling sheeting, table or counter top sheeting, and the like. In another embodiment, the present invention is physically adhered to a surface, such as a floor or a wall, via an adhesive material. Preferably, this adhesive is a conductive adhesive such that a continuous conductive path is formed from the tile or sheeting material 5 of the present invention and the floor or wall backing to which it is adhered. In one embodiment, an adhesive layer is formed directly onto the tile or sheeting material 5. In yet another embodiment, the tile material 5 comprises a base resin that is rigid enough to be applied to an elevated floor or to a dropped ceiling. In these applications, each tile 5 is mounted into a supporting grid. In computer centers that require ventilation through the ceiling or floor, the electrically conductive flooring tile 5 includes ventilation holes.

In another embodiment, the top surface 20 of the tile or sheeting material 5 has a texture useful for improving traction. According to one embodiment, this top surface texture 20 is formed by embossing a pattern into the conductive loaded resin-based material substrate 10. In another embodiment, the pattern in molded into the substrate 10 during the molding process.

The tile or sheeting material 5 may be formed by any of several methods. In one embodiment, individual tiles of the conductive loaded resin-based material are injection molded. In another embodiment, a continuous sheet of the conductive loaded resin-based material is extruded. In yet another embodiment, a continuous sheet of the conductive loaded resin-based material is formed by calendaring. In another embodiment, a continuous sheet of the conductive loaded resin-based material that has been formed by extrusion or by calendaring is then cut into individual tiles. According to various embodiments, the sheeting is cut by pressing, hot knife, water jetting, sawing, and the like.

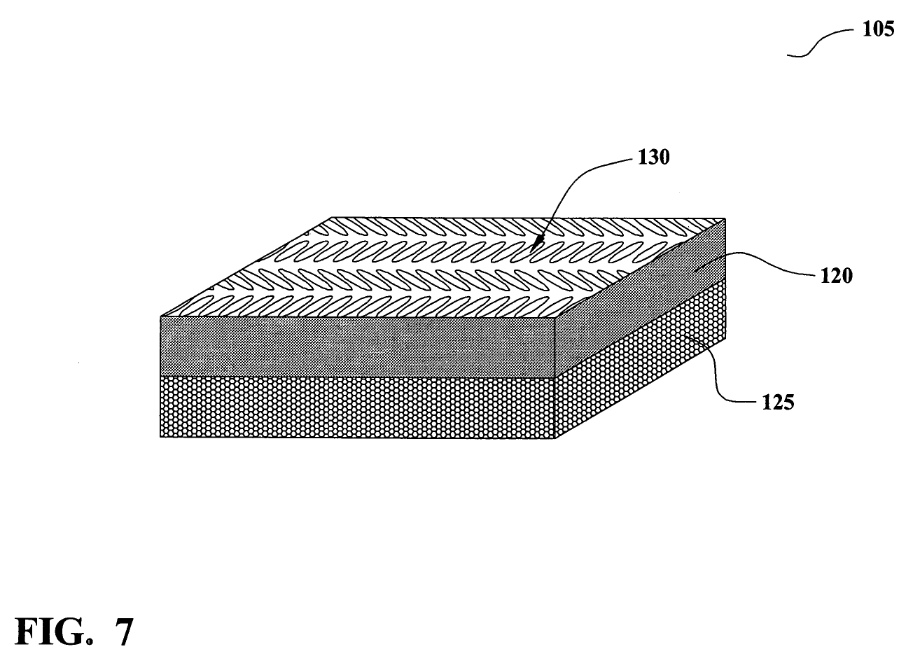

Referring now to FIG. 7, a second preferred embodiment of the present invention is illustrated. Another conductive tile or sheeting 105 is shown. In this embodiment, the electrically conductive flooring tile includes two layers 120 and 125. The top layer 120 comprises a solid conductive loaded resin-based material 120. The bottom layer 125 comprises a foamed conductive loaded resin-based material 125. This embodiment 105 provides a top layer 120 that is strong and durable with a bottom layer 125 that cushions to reduce walking fatigue. Both top and bottom layers 120 and 125 comprises the conductive loaded resin-based material such that the needed conductive properties for the tile or sheeting material are achieved.

In addition embodiments, the conductive loaded resin-based material of the present invention is formed as sheet flooring, mats, or runners. In another embodiment of the present invention, a power terminal connection is formed into the flooring material such that the flooring can be used as a heating source. In yet another embodiment, a grounding wire is embedded into the flooring.

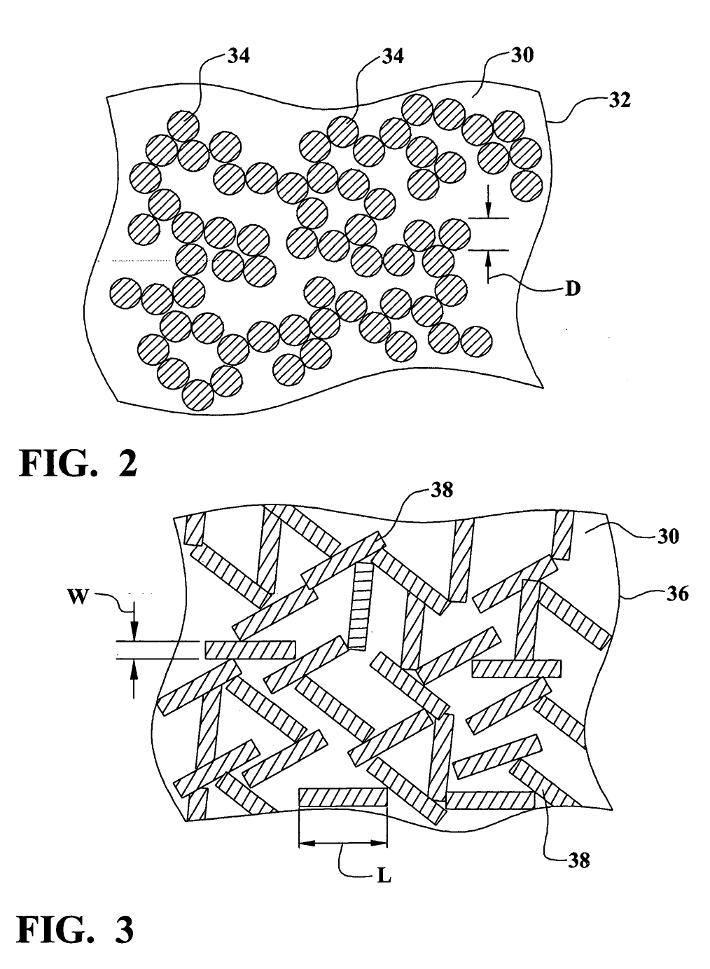

The conductive loaded resin-based material of the present invention typically comprises a micron powder(s) of conductor particles and/or in combination of micron fiber(s) substantially homogenized within a base resin host. FIG. 2 shows cross section view of an example of conductor loaded resin-based material 32 having powder of conductor particles 34 in a base resin host 30. In this example the diameter D of the conductor particles 34 in the powder is between about 3 and 12 microns.

FIG. 3 shows a cross section view of an example of conductor loaded resin-based material 36 having conductor fibers 38 in a base resin host 30. The conductor fibers 38 have a diameter of between about 3 and 12 microns, typically in the range of 10 microns or between about 8 and 12 microns, and a length of between about 2 and 14 millimeters. The micron conductive fibers 38 may be metal fiber or metal plated fiber. Further, the metal plated fiber may be formed by plating metal onto a metal fiber or by plating metal onto a non-metal fiber. Exemplary metal fibers include, but are not limited to, stainless steel fiber, copper fiber, nickel fiber, silver fiber, aluminum fiber, or the like, or combinations thereof. Exemplary metal plating materials include, but are not limited to, copper, nickel, cobalt, silver, gold, palladium, platinum, ruthenium, and rhodium, and alloys of thereof. Any platable fiber may be used as the core for a non-metal fiber. Exemplary non-metal fibers include, but are not limited to, carbon, graphite, polyester, basalt, man-made and naturally-occurring materials, and the like. In addition, superconductor metals, such as titanium, nickel, niobium, and zirconium, and alloys of titanium, nickel, niobium, and zirconium may also be used as micron conductive fibers and/or as metal plating onto fibers in the present invention.

These conductor particles and or fibers are substantially homogenized within a base resin. As previously mentioned, the conductive loaded resin-based materials have a sheet resistance between about 5 and 25 ohms per square, though other values can be achieved by varying the doping parameters and/or resin selection. To realize this sheet resistance the weight of the conductor material comprises between about 20% and about 50% of the total weight of the conductive loaded resin-based material. More preferably, the weight of the conductive material comprises between about 20% and about 40% of the total weight of the conductive loaded resin-based material. More preferably yet, the weight of the conductive material comprises between about 25% and about 35% of the total weight of the conductive loaded resin-based material. Still more preferably yet, the weight of the conductive material comprises about 30% of the total weight of the conductive loaded resin-based material. Stainless Steel Fiber of 6-12 micron in diameter and lengths of 4-6 mm and comprising, by weight, about 30% of the total weight of the conductive loaded resin-based material will produce a very highly conductive parameter, efficient within any EMF spectrum. Referring now to FIG. 4, another preferred embodiment of the present invention is illustrated where the conductive materials comprise a combination of both conductive powders 34 and micron conductive fibers 38 substantially homogenized together within the resin base 30 during a molding process.

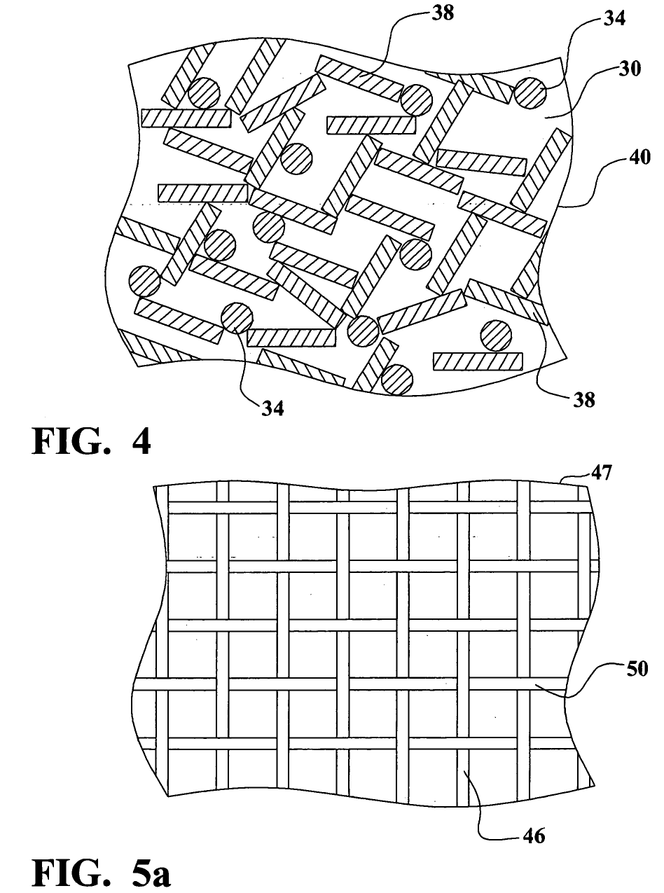

Referring now to FIGS. 5a and 5b, a preferred composition of the conductive loaded, resin-based material is illustrated. The conductive loaded resin-based material can be formed into fibers or textiles that are then woven or webbed into a conductive fabric. The conductive loaded resin-based material is formed in strands that can be woven as shown. FIG. 5a shows a conductive fabric 42 where the fibers are woven together in a two-dimensional weave 46 and 50 of fibers or textiles. FIG. 5b shows a conductive fabric 42′ where the fibers are formed in a webbed arrangement. In the webbed arrangement, one or more continuous strands of the conductive fiber are nested in a random fashion. The resulting conductive fabrics or textiles 42, see FIG. 5a, and 42′, see FIG. 5b, can be made very thin, thick, rigid, flexible or in solid form(s).

Similarly, a conductive, but cloth-like, material can be formed using woven or webbed micron stainless steel fibers, or other micron conductive fibers. These woven or webbed conductive cloths could also be sandwich laminated to one or more layers of materials such as Polyester(s), Teflon(s), Kevlar(s) or any other desired resin-based materials(). This conductive fabric may then be cut into desired shapes and sizes.

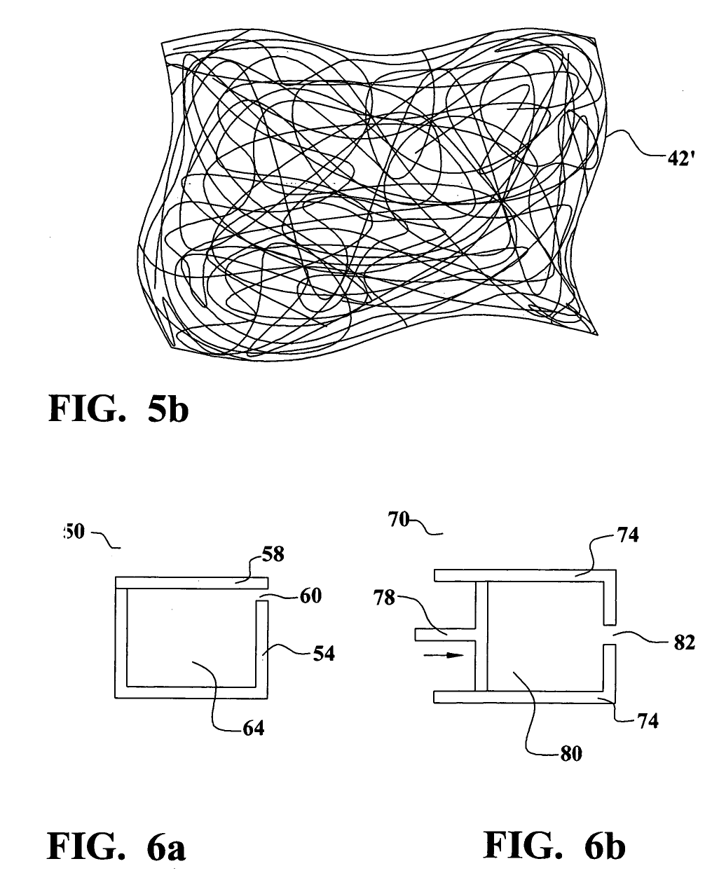

Electrically conductive flooring tile formed from conductive loaded resin-based materials can be formed or molded in a number of different ways including injection molding, extrusion or chemically induced molding or forming. FIG. 6a shows a simplified schematic diagram of an injection mold showing a lower portion 54 and upper portion 58 of the mold 50. Conductive loaded blended resin-based material is injected into the mold cavity 64 through an injection opening 60 and then the substantially homogenized conductive material cures by thermal reaction. The upper portion 58 and lower portion 54 of the mold are then separated or parted and the tiles are removed.

FIG. 6b shows a simplified schematic diagram of an extruder 70 for forming electrically conductive flooring tile using extrusion. Conductive loaded resin-based material(s) is placed in the hopper 80 of the extrusion unit 74. A piston, screw, press or other means 78 is then used to force the thermally molten or a chemically induced curing conductive loaded resin-based material through an extrusion opening 82 which shapes the thermally molten curing or chemically induced cured conductive loaded resin-based material to the desired shape. The conductive loaded resin-based material is then fully cured by chemical reaction or thermal reaction to a hardened or pliable state and is ready for use. Thermoplastic or thermosetting resin-based materials and associated processes may be used in molding the conductive loaded resin-based articles of the present invention.

The advantages of the present invention may now be summarized. An effective conductive flooring is achieved. A conductive floor tile and a conductive floor sheeting are achieved. Methods to form conductive flooring are achieved. The electrical, thermal, or ESD characteristics of the conductive flooring can be altered or the visual characteristics can be altered by forming a metal layer over the conductive loaded resin-based material. The conductive flooring is formed from conductive loaded resin-based material incorporating various forms of the material.

As shown in the preferred embodiments, the novel methods and devices of the present invention provide an effective and manufacturable alternative to the prior art.

While the invention has been particularly shown and described with reference to the preferred embodiments thereof, it will be understood by those skilled in the art that various changes in form and details may be made without departing from the spirit and scope of the invention.

1. A conductive flooring device comprising a conductive loaded, resin-based material comprising conductive materials in a base resin host wherein the weight of said conductive materials is between 20% and 50% of the total 5 weight of said conductive loaded resin-based material.

2. The device according to claim 1 wherein said conductive materials comprise micron conductive fiber.

3. The device according to claim 2 wherein said conductive materials further comprise conductive powder.

4. The device according to claim 1 wherein said conductive materials are metal.

5. The device according to claim 1 wherein said conductive materials are non-conductive materials with metal plating.

6. The device according to claim 1 wherein said conductive flooring device comprises a conductive tile.

7. The device according to claim 1 wherein said conductive flooring device comprises a continuous sheet.

8. The device according to claim 1 wherein said conductive flooring device comprises a first layer and a second layer, wherein said first layer comprises a solid said conductive loaded resin-based material.

9. The device according to claim 8 wherein said second layer comprises a foamed said conductive loaded resin-based material.

10. The device according to claim 1 wherein said conductive flooring device further comprises a traction enhancing surface.

11. A conductive flooring device comprising a conductive loaded, resin-based material comprising micron conductive fiber in a base resin host wherein the weight of said micron conductive fiber is between 20% and 50% of the total weight of said conductive loaded resin-based material.

12. The device according to claim 11 wherein said micron conductive fiber is nickel plated carbon micron fiber, stainless steel micron fiber, copper micron fiber, silver micron fiber or combinations thereof.

13. The device according to claim 11 wherein said conductive loaded resin-based material further comprises conductive powder.

14. The device according to claim 13 wherein said conductive powder is nickel, copper, or silver.

15. The device according to claim 13 wherein said conductive powder is a non-conductive material with a metal plating of nickel, copper, silver, or alloys thereof.

16. The device according to claim 11 wherein said conductive flooring device comprises a conductive tile.

17. The device according to claim 11 wherein said conductive flooring device comprises a continuous sheet.

18. The device according to claim 11 wherein said conductive flooring device comprises a first layer and a second layer, wherein said first layer comprises a solid said conductive loaded resin-based material.

19. The device according to claim 18 wherein said second layer comprises a foamed said conductive loaded resin-based material.

20. The device according to claim 11 wherein said conductive flooring device further comprises a traction enhancing surface.

21. A conductive flooring device comprising:
a first layer comprising a first conductive loaded, resin-based material comprising conductive materials in a base resin host wherein the weight of said conductive materials is between 20% and 50% of the total weight of said first conductive loaded resin-based material and wherein said conductive loaded resin-based material is a solid; and
a second layer comprising a second conductive loaded resin-based material comprising conductive materials in a base resin host wherein said second conductive loaded resin-based material is a foamed material.

22. The device according to claim 21 wherein said conductive materials comprise micron conductive fiber.

23. The device according to claim 22 further comprising conductive powder.

24. The device according to claim 22 wherein said micron conductive fiber has a diameter of between about 3 μm and about 12 μm and a length of between about 2 mm and about 14 mm.

25. The device according to claim 21 wherein said conductive flooring device comprises a conducive tile.
